(19) United States
(12) Patent Application Publication
(10) Pub. No.: US 2024/0047173 A1
(43) Pub. Date: Feb. 8, 2024

(54) MONOLITHIC DETECTOR

(71) Applicant: ASML Netherlands B.V., Veldhoven (NL)

(72) Inventors: Matthias OBERST, Nürnberg (DE); Harald Gert Helmut NEUBAUER, Erlangen (DE); Thomas SCHWEIGER, Nürnberg (DE)

(73) Assignee: ASML Netherlands B.V., Veldhoven (NL)

(21) Appl. No.: 18/258,522

(22) PCT Filed: Dec. 10, 2021
(86) PCT No.: PCT/EP2021/085159

§ 371 Date: Jun. 20, 2023

Related U.S. Application Data
(60) Provisional application No. 63/130,210, filed on Dec. 23, 2020.

(51) Int. Cl. H01J 37/244

(52) U.S. Cl. CPC H01J 37/244; H01J 2237/2441; H01J 2237/24495; H01J 2237/2446

(57) ABSTRACT

A monolithic detector may be used in a charged particle beam apparatus. The detector may include a plurality of sensing elements formed on a first side of a semiconductor substrate, each of the sensing elements configured to receive charged particles emitted from a sample and to generate carriers in proportion to a first property of a received charged particle, and a plurality of signal processing components formed on a second side of the semiconductor substrate, the plurality of signal processing components being part of a system configured to determine a value that represents a second property of the received charged particle. The substrate may have a thickness in a range from about 10 to 30 μm. The substrate may include a region configured to insulate the plurality of sensing elements formed on the first side from the plurality of signal processing components formed on the second side.

### CROSS-REFERENCE TO RELATED APPLICATIONS

This application claims priority of U.S. application 63/130,210 which was filed on Dec. 23, 2020 and which is incorporated herein in its entirety by reference.

### FIELD

The description herein relates to detectors, and more particularly, to detectors that may be applicable to charged particle detection.

### BACKGROUND

Detectors may be used for sensing physically observable phenomena. For example, charged particle beam tools, such as electron microscopes, may comprise detectors that receive charged particles projected from a sample and that output detection signals. Detection signals may be used to reconstruct images of sample structures under inspection and may be used, for example, to reveal defects in the sample. Detection of defects in a sample is increasingly important in the manufacturing of semiconductor devices, which may include large numbers of densely packed, miniaturized integrated circuit (IC) components. Inspection systems may be provided as dedicated tools for this purpose.

With continuing miniaturization of semiconductor devices, inspection systems may use lower and lower beam currents in charged particle beam tools. Meanwhile, a detector may require flexibility for detecting multiple beams that may land on the detector with unknown sizes and at unknown positions. A detector array may be pixelated in an array of sensing elements that can adapt to different shapes and sizes of beams. Existing detection systems may be limited by signal-to-noise ratio (SNR) and system throughput, particularly when beam current reduces to, for example, pico-ampere ranges. Some applications may demand high speed, high throughput, high bandwidth, and the like. But as detector arrays become more complicated (e.g., larger arrays, with more sensing elements), wiring associated with signal processing and signal readout may become longer, which may result in bandwidth reduction, especially if interconnections are not well planned and designed. This may prevent a detection system from achieving desired bandwidth. In addition, long interconnections within analog signal paths may introduce higher noise and interference to the signal paths. As a result, a signal-to-noise ratio of the detection system may be deteriorated. Improvements in detection systems and methods are thus desired.

### SUMMARY

Embodiments of the present disclosure provide systems and methods for detection based on charged particle beams. In some embodiments, there may be provided a charged particle beam system that includes a detector. A monolithic detector may be used in a charged particle beam apparatus. The detector may include a plurality of sensing elements formed on a first side of a semiconductor substrate, each of the sensing elements configured to receive charged particles emitted from a sample and to generate carriers in proportion to a first property of a received charged particle, and a plurality of signal processing components formed on a second side of the semiconductor substrate, the plurality of signal processing components being part of a system configured to determine a value that represents a second property of the received charged particle. The substrate may have a thickness in a range from about 10 to 30 μm. The substrate may include a region configured to insulate the plurality of sensing elements formed on the first side from the plurality of signal processing components formed on the second side.

It is to be understood that both the foregoing general description and the following detailed description are exemplary and explanatory only and are not restrictive of the disclosed embodiments, as may be claimed.

### BRIEF DESCRIPTION OF THE DRAWINGS

The above and other aspects of the present disclosure will become more apparent from the description of exemplary embodiments, taken in conjunction with the accompanying drawings.

FIG. 1 is a diagrammatic representation of an exemplary electron beam inspection (EBI) system, consistent with embodiments of the present disclosure.

FIGS. 2A and 2B are diagrams illustrating a charged particle beam apparatus that may be an example of an electron beam tool, consistent with embodiments of the present disclosure.

FIGS. 3A and 3B are diagrammatic representations of an exemplary structure of a detector, consistent with embodiments of the present disclosure.

FIG. 4 is a diagrammatic representation of a detector, consistent with embodiments of the present disclosure.

FIGS. 5A and 5B are diagrammatic representation of a monolithic layer of a detector, consistent with embodiments of the present disclosure.

FIG. 6 is a diagrammatic representation of a sensing element that may form at least a part of monolithic layer, consistent with embodiments of the present disclosure.

FIG. 7 is a diagrammatic representation of a sensing element that may form a portion of a monolithic layer, consistent with embodiments of the present disclosure.

FIG. 8 is a flow chart of a charged particle detection method, consistent with embodiments of the present disclosure.

### DETAILED DESCRIPTION

Reference will now be made in detail to exemplary embodiments, examples of which are illustrated in the drawings. The following description refers to the accompanying drawings in which the same numbers in different drawings represent the same or similar elements unless otherwise represented. The implementations set forth in the following description of exemplary embodiments do not represent all implementations consistent with the invention. Instead, they are merely examples of apparatuses, systems, and methods consistent with aspects related to subject matter that may be recited in the appended claims.

Electronic devices are constructed of circuits formed on a piece of silicon called a substrate. Many circuits may be formed together on the same piece of silicon and are called integrated circuits or ICs. With advancements in technology, the size of these circuits has decreased dramatically so that many more of them can fit on the substrate. For example, an IC chip in a smart phone can be as small as a fingernail and yet may include over 2 billion transistors, the size of each transistor being less than 1/1,000th the width of a human hair.

Making these extremely small ICs is a complex, time-consuming, and expensive process, often involving hundreds of individual steps. Errors in even one step have the potential to result in defects in the finished IC, rendering it useless. Thus, one goal of the manufacturing process is to avoid such defects to maximize the number of functional ICs made in the process, that is, to improve the overall yield of the process.

One component of improving yield is monitoring the chip making process to ensure that it is producing a sufficient number of functional integrated circuits. One way to monitor the process is to inspect the chip circuit structures at various stages of their formation. Inspection can be carried out using a scanning electron microscope (SEM). A SEM can be used to image these extremely small structures, in effect, taking a “picture” of the structures. The image can be used to determine if the structure was formed properly and also if it was formed in the proper location. If the structure is defective, then the process can be adjusted so the defect is less likely to recur. To enhance throughput (e.g., the number of samples processed per hour), it is desirable to conduct inspection as quickly as possible.

An image of a wafer may be formed by scanning a primary beam of a SEM system (e.g., a “probe” beam) over the wafer and collecting particles (e.g., secondary electrons) generated from the wafer surface at a detector. Secondary electrons may form a beam (a “secondary beam”) that is directed toward the detector. Secondary electrons landing on the detector may cause electrical signals (e.g., current, charge, or voltage) to be generated in the detector. These signals may be output from the detector and may be processed by an image processor to form the image of the sample.

A detector may include a pixelated array of multiple sensing elements. A pixelated array may be useful because it may allow adaptation to the size and shape of beam spots formed on the detector. When multiple primary beams are used, with multiple secondary beams incident on the detector, a pixelated array may be helpful to segregate different regions of the detector associated with different beam spots. Multiple beams may land on the detector with unknown sizes and at unknown positions, thus forming different beam spots that may cover different pixels (e.g., individual sensing elements) of the array.

A detector may include circuitry configured to process signals generated in individual sensing elements, such as a read-out integrated circuit (“ROIC”). The sensing elements may include one or more diodes that may convert incident energy into a measurable signal. Circuitry of the detector may include wiring paths configured to route signals to various locations or electrical components configured to perform particular functions. An electron beam spot may cover multiple sensing elements on the detector, and signals generated in the sensing elements may be routed together. Circuitry included in a detector may include a wiring path that routes output from individual sensing elements that are grouped together (e.g., by virtue of being covered by the same electron beam spot) to a common output. The circuitry may also include electrical components such as switches configured to connect sensing elements that are grouped together.

Typically, a detector is created by bonding together two separate chips, one including sensing elements and one including circuitry. Each chip may be thin, and safe handling may be difficult. Making connections between the separate chips may introduce complications, such as the need to accurately align and reliably bond all connections between the chips. Furthermore, loss may be incurred at various junctions between the chips. Loss may lead to a reduction in signal-to-noise ratio (SNR).

To conduct inspection as quickly as possible, a detector may be an important component in a charged particle beam system. For example, speed of forming a picture of a sample under inspection may be related to speed at which output is read out from the detector (“readout speed”). Therefore, it would be desirable to provide a detector that enables high speed readout.

However, a competing objective of charged particle beam system design may include component packaging. Packaging may refer to the ability to pack components into a desired form factor. Typically, in a charged particle beam system, space is at a premium. Thus, it would be desirable to provide a detector that is small. A detector may be formed as a semiconductor device, and an important dimension in minimizing size may be thickness. Thus, it would be desirable to provide a detector that minimizes thickness.

In some embodiments of the disclosure, a detector may be provided as a monolithic device. The detector may include both sensing elements and circuitry for performing charged particle detection (e.g., readout circuitry). Sensing elements may be formed in a substrate of the detector. Semiconductor manufacturing techniques may be used to form circuitry, including wiring paths and transistors, on an opposite side of the detector from the sensing elements.

In some embodiments, a detector capable of high speed readout may be provided in a thin semiconductor package. The need to assemble separate devices (e.g., a sensor die and a circuit die) may be eliminated. Furthermore, interconnections between components may be minimized Loss associated with connections between components may be reduced or eliminated. Also, thinning of a detector may be made easier. A carrier may be more easily attached to a top side of the detector.

Objects and advantages of the disclosure may be realized by the elements and combinations as set forth in the embodiments discussed herein. However, embodiments of the present disclosure are not necessarily required to achieve such exemplary objects or advantages, and some embodiments may not achieve any of the stated objects or advantages.

Without limiting the scope of the present disclosure, some embodiments may be described in the context of providing detection systems and detection methods in systems utilizing electron beams (“e-beams”). However, the disclosure is not so limited. Other types of charged particle beams may be similarly applied. Furthermore, systems and methods for detection may be used in other imaging systems, such as optical imaging, photon detection, x-ray detection, ion detection, etc.

As used herein, unless specifically stated otherwise, the term “or” encompasses all possible combinations, except where infeasible. For example, if it is stated that a component includes A or B, then, unless specifically stated otherwise or infeasible, the component may include A, or B, or A and B. As a second example, if it is stated that a component includes A, B, or C, then, unless specifically stated otherwise or infeasible, the component may include A, or B, or C, or A and B, or A and C, or B and C, or A and B and C. Expressions such as “at least one of” do not necessarily modify an entirety of a following list and do not necessarily modify each member of the list, such that “at least one of A, B, and C” should be understood as including only one of A, only one of B, only one of C, or any combination of A, B, and C. The phrase “one of A and B” or “any one of A and B” shall be interpreted in the broadest sense to include one of A, or one of B.

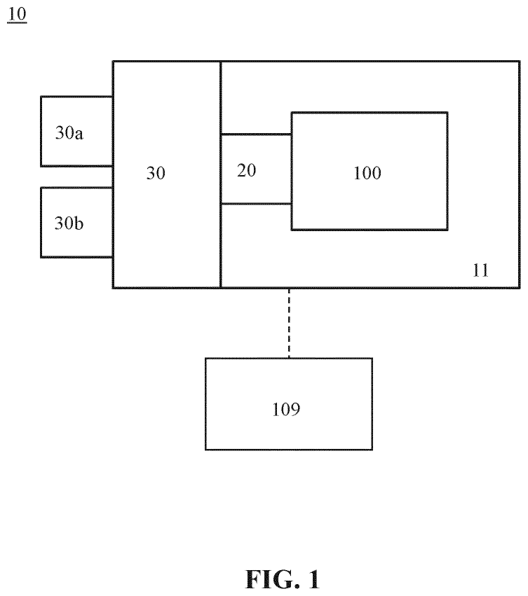

Reference is now made to FIG. 1, which illustrates an exemplary electron beam inspection (EBI) system 10 that may be used for wafer inspection, consistent with embodiments of the present disclosure. As shown in FIG. 1, EBI system 10 includes a main chamber 11 a load/lock chamber 20, an electron beam tool 100 (e.g., a scanning electron microscope (SEM)), and an equipment front end module (EFEM) 30. Electron beam tool 100 is located within main chamber 11 and may be used for imaging. EFEM 30 includes a first loading port 30a and a second loading port 30b. EFEM 30 may include additional loading ports. First loading port 30a and second loading port 30b receive wafer front opening unified pods (FOUPs) that contain wafers (e.g., semiconductor wafers or wafers made of other materials) or samples to be inspected (wafers and samples may be collectively referred to as “wafers” herein).

One or more robotic arms (not shown) in EFEM 30 may transport the wafers to load/lock chamber 20. Load/lock chamber 20 is connected to a load/lock vacuum pump system (not shown) which removes gas molecules in load/lock chamber 20 to reach a first pressure below the atmospheric pressure. After reaching the first pressure, one or more robotic arms (not shown) may transport the wafer from load/lock chamber 20 to main chamber 11. Main chamber 11 is connected to a main chamber vacuum pump system (not shown) which removes gas molecules in main chamber 11 to reach a second pressure below the first pressure. After reaching the second pressure, the wafer is subject to inspection by electron beam tool 100. Electron beam tool 100 may be a single-beam system or a multi-beam system. A controller 109 is electronically connected to electron beam tool 100, and may be electronically connected to other components as well. Controller 109 may be a computer configured to execute various controls of EBI system 10. While controller 109 is shown in FIG. 1 as being outside of the structure that includes main chamber 11, load/lock chamber 20, and EFEM 30, it is appreciated that controller 109 can be part of the structure.

A charged particle beam microscope, such as that formed by or which may be included in EBI system 10, may be capable of resolution down to, e.g., the nanometer scale, and may serve as a practical tool for inspecting IC components on wafers. With an e-beam system, electrons of a primary electron beam may be focused at probe spots on a sample (e.g., a wafer) under inspection. The interactions of the primary electrons with the wafer may result in secondary particle beams being formed. The secondary particle beams may comprise backscattered electrons, secondary electrons, or Auger electrons, etc. resulting from the interactions of the primary electrons with the wafer. Characteristics of the secondary particle beams (e.g., intensity) may vary based on the properties of the internal or external structures or materials of the wafer, and thus may indicate whether the wafer includes defects.

The intensity of the secondary particle beams may be determined using a detector. The secondary particle beams may form beam spots on a surface of the detector. The detector may generate electrical signals (e.g., a current, a charge, a voltage, etc.) that represent intensity of the detected secondary particle beams. The electrical signals may be measured with measurement circuitries which may include further components (e.g., analog-to-digital converters) to obtain a distribution of the detected electrons. The electron distribution data collected during a detection time window, in combination with corresponding scan path data of the primary electron beam incident on the wafer surface, may be used to reconstruct images of the wafer structures or materials under inspection. The reconstructed images may be used to reveal various features of the internal or external structures or materials of the wafer and may be used to reveal defects that may exist in the wafer.

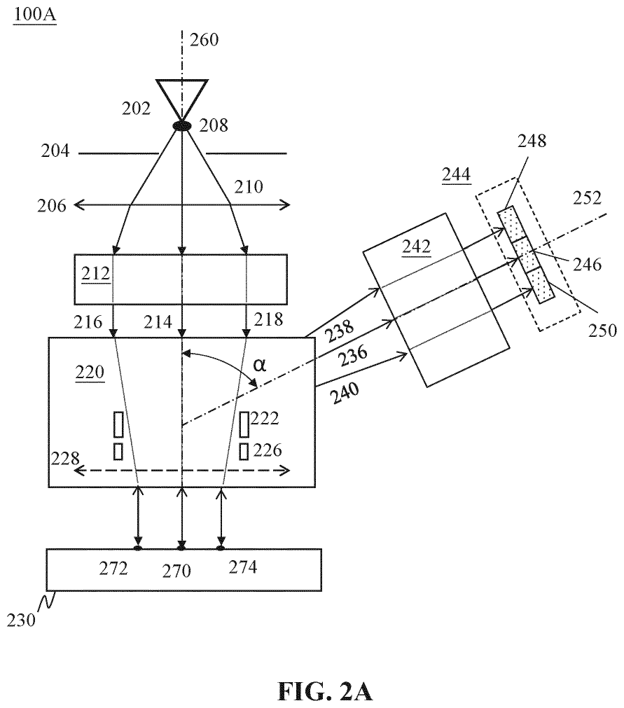

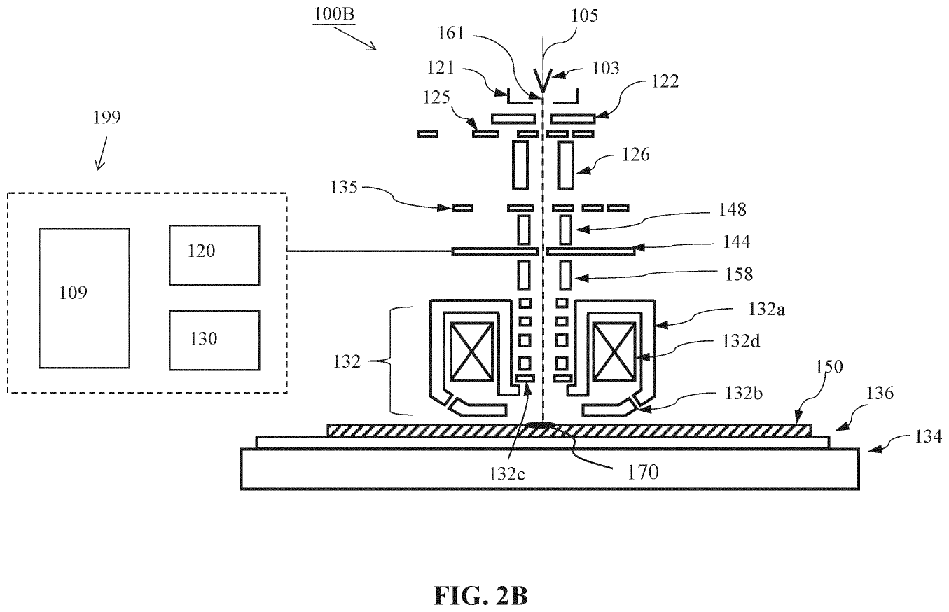

FIG. 2A illustrates a charged particle beam apparatus that may be an example of electron beam tool 100, consistent with embodiments of the present disclosure. FIG. 2A shows an apparatus that uses a plurality of beamlets formed from a primary electron beam to simultaneously scan multiple locations on a wafer.

As shown in FIG. 2A, electron beam tool 100A may comprise an electron source 202, a gun aperture 204, a condenser lens 206, a primary electron beam 210 emitted from electron source 202, a source conversion unit 212, a plurality of beamlets 214, 216, and 218 of primary electron beam 210, a primary projection optical system 220, a wafer stage (not shown in FIG. 2A), multiple secondary electron beams 236, 238, and 240, a secondary optical system 242, and electron detection device 244. Electron source 202 may generate primary particles, such as electrons of primary electron beam 210. A controller, image processing system, and the like may be coupled to electron detection device 244. Primary projection optical system 220 may comprise beam separator 222, deflection scanning unit 226, and objective lens 228. Electron detection device 244 may comprise detection sub-regions 246, 248, and 250.

Electron source 202, gun aperture 204, condenser lens 206, source conversion unit 212, beam separator 222, deflection scanning unit 226, and objective lens 228 may be aligned with a primary optical axis 260 of apparatus 100A. Secondary optical system 242 and electron detection device 244 may be aligned with a secondary optical axis 252 of apparatus 100A.

Electron source 202 may comprise a cathode, an extractor or an anode, wherein primary electrons can be emitted from the cathode and extracted or accelerated to form a primary electron beam 210 with a crossover (virtual or real) 208. Primary electron beam 210 can be visualized as being emitted from crossover 208. Gun aperture 204 may block off peripheral electrons of primary electron beam 210 to reduce size of probe spots 270, 272, and 274.

Source conversion unit 212 may comprise an array of image-forming elements (not shown in FIG. 2A) and an array of beam-limit apertures (not shown in FIG. 2A). An example of source conversion unit 212 may be found in U.S. Pat. No. 9,691,586; U.S. Publication No. 2017/0025243; and International Application No. PCT/EP2017/084429, all of which are incorporated by reference in their entireties. The array of image-forming elements may comprise an array of micro-deflectors or micro-lenses. The array of image-forming elements may form a plurality of parallel images (virtual or real) of crossover 208 with a plurality of beamlets 214, 216, and 218 of primary electron beam 210. The array of beam-limit apertures may limit the plurality of beamlets 214, 216, and 218.

Condenser lens 206 may focus primary electron beam 210. The electric currents of beamlets 214, 216, and 218 downstream of source conversion unit 212 may be varied by adjusting the focusing power of condenser lens 206 or by changing the radial sizes of the corresponding beam-limit apertures within the array of beam-limit apertures. Condenser lens 206 may be an adjustable condenser lens that may be configured so that the position of its first principal plane is movable. The adjustable condenser lens may be configured to be magnetic, which may result in off-axis beamlets 216 and 218 landing on the beamlet-limit apertures with rotation angles. The rotation angles change with the focusing power and the position of the first principal plane of the adjustable condenser lens. In some embodiments, the adjustable condenser lens may be an adjustable anti-rotation condenser lens, which involves an anti-rotation lens with a movable first principal plane. An example of an adjustable condenser lens is further described in U.S. Publication No. 2017/0025241, which is incorporated by reference in its entirety.

Objective lens 228 may focus beamlets 214, 216, and 218 onto a wafer 230 for inspection and may form a plurality of probe spots 270, 272, and 274 on the surface of wafer 230. Secondary electron beamlets 236, 238, and 240 may be formed that are emitted from wafer 230 and travel back toward beam separator 222.

Beam separator 222 may be a beam separator of Wien filter type generating an electrostatic dipole field and a magnetic dipole field. In some embodiments, if they are applied, the force exerted by electrostatic dipole field on an electron of beamlets 214, 216, and 218 may be equal in magnitude and opposite in direction to the force exerted on the electron by magnetic dipole field. Beamlets 214, 216, and 218 can therefore pass straight through beam separator 222 with zero deflection angle. However, the total dispersion of beamlets 214, 216, and 218 generated by beam separator 222 may also be non-zero. Beam separator 222 may separate secondary electron beams 236, 238, and 240 from beamlets 214, 216, and 218 and direct secondary electron beams 236, 238, and 240 towards secondary optical system 242.

Deflection scanning unit 226 may deflect beamlets 214, 216, and 218 to scan probe spots 270, 272, and 274 over an area on a surface of wafer 230. In response to incidence of beamlets 214, 216, and 218 at probe spots 270, 272, and 274, secondary electron beams 236, 238, and 240 may be emitted from wafer 230. Secondary electron beams 236, 238, and 240 may comprise electrons with a distribution of energies including secondary electrons and backscattered electrons. Secondary optical system 242 may focus secondary electron beams 236, 238, and 240 onto detection sub-regions 246, 248, and 250 of electron detection device 244. Detection sub-regions 246, 248, and 250 may be configured to detect corresponding secondary electron beams 236, 238, and 240 and generate corresponding signals used to reconstruct an image of the surface of wafer 230. Detection sub-regions 246, 248, and 250 may include separate detector packages, separate sensing elements, or separate regions of an array detector. In some embodiments, each detection sub-region may include a single sensing element.

Another example of a charged particle beam apparatus will now be discussed with reference to FIG. 2B. An electron beam tool 100B (also referred to herein as apparatus 100B) may be an example of electron beam tool 100 and may be similar to electron beam tool 100A shown in FIG. 2A. However, different from apparatus 100A, apparatus 100B may be a single-beam tool that uses only one primary electron beam to scan one location on the wafer at a time.

As shown in FIG. 2B, apparatus 100B includes a wafer holder 136 supported by motorized stage 134 to hold a wafer 150 to be inspected. Electron beam tool 100B includes an electron emitter, which may comprise a cathode 103, an anode 121, and a gun aperture 122. Electron beam tool 100B further includes a beam limit aperture 125, a condenser lens 126, a column aperture 135, an objective lens assembly 132, and a detector 144. Objective lens assembly 132, in some embodiments, may be a modified SORIL lens, which includes a pole piece 132a, a control electrode 132b, a deflector 132c, and an exciting coil 132d. In a detection or imaging process, an electron beam 161 emanating from the tip of cathode 103 may be accelerated by anode 121 voltage, pass through gun aperture 122, beam limit aperture 125, condenser lens 126, and be focused into a probe spot 170 by the modified SORIL lens and impinge onto the surface of wafer 150. Probe spot 170 may be scanned across the surface of wafer 150 by a deflector, such as deflector 132c or other deflectors in the SORIL lens. Secondary or scattered particles, such as secondary electrons or scattered primary electrons emanated from the wafer surface may be collected by detector 144 to determine intensity of the beam and so that an image of an area of interest on wafer 150 may be reconstructed.

There may also be provided an image processing system 199 that includes an image acquirer 120, a storage 130, and controller 109. Image acquirer 120 may comprise one or more processors. For example, image acquirer 120 may comprise a computer, server, mainframe host, terminals, personal computer, any kind of mobile computing devices, and the like, or a combination thereof. Image acquirer 120 may connect with detector 144 of electron beam tool 100B through a medium such as an electrical conductor, optical fiber cable, portable storage media, IR, Bluetooth, internet, wireless network, wireless radio, or a combination thereof. Image acquirer 120 may receive a signal from detector 144 and may construct an image. Image acquirer 120 may thus acquire images of wafer 150. Image acquirer 120 may also perform various post-processing functions, such as image averaging, generating contours, superimposing indicators on an acquired image, and the like. Image acquirer 120 may be configured to perform adjustments of brightness and contrast, etc. of acquired images. Storage 130 may be a storage medium such as a hard disk, random access memory (RAM), cloud storage, other types of computer readable memory, and the like. Storage 130 may be coupled with image acquirer 120 and may be used for saving scanned raw image data as original images, and post-processed images. Image acquirer 120 and storage 130 may be connected to controller 109. In some embodiments, image acquirer 120, storage 130, and controller 109 may be integrated together as one electronic control unit.

In some embodiments, image acquirer 120 may acquire one or more images of a sample based on an imaging signal received from detector 144. An imaging signal may correspond to a scanning operation for conducting charged particle imaging. An acquired image may be a single image comprising a plurality of imaging areas that may contain various features of wafer 150. The single image may be stored in storage 130. Imaging may be performed on the basis of imaging frames.

The condenser and illumination optics of the electron beam tool may comprise or be supplemented by electromagnetic quadrupole electron lenses. For example, as shown in FIG. 2B, electron beam tool 100B may comprise a first quadrupole lens 148 and a second quadrupole lens 158. In some embodiments, the quadrupole lenses may be used for controlling the electron beam. For example, first quadrupole lens 148 may be controlled to adjust the beam current and second quadrupole lens 158 may be controlled to adjust the beam spot size and beam shape.

FIG. 2B illustrates a charged particle beam apparatus that may use a single primary beam configured to generate secondary electrons by interacting with wafer 150. Detector 144 may be placed along optical axis 105, as in the embodiment shown in FIG. 2B. The primary electron beam may be configured to travel along optical axis 105. Accordingly, detector 144 may include a hole at its center so that the primary electron beam may pass through to reach wafer 150. FIG. 2B shows an example of detector 144 having an opening at its center. However, some embodiments may use a detector placed off-axis relative to the optical axis along which the primary electron beam travels. For example, as in the embodiment shown in FIG. 2A, discussed above, a beam separator 222 may be provided to direct secondary electron beams toward a detector placed off-axis. Beam separator 222 may be configured to divert secondary electron beams by an angle α toward an electron detection device 244, as shown in FIG. 2A.

A detector in a charged particle beam system may include one or more sensing elements. The detector may comprise a single-element detector or an array with multiple sensing elements. The sensing elements may be configured for charged particle counting. Sensing elements of a detector that may be useful for charged particle counting are discussed in U.S. Publication No. 2019/0378682, which is incorporated by reference in its entirety. In some embodiments, sensing elements may be configured for signal level intensity detection.

Sensing elements may include a diode or an element similar to a diode that may convert incident energy into a measurable signal. For example, sensing elements in a detector may include a PIN diode. Throughout this disclosure, sensing elements may be represented as a diode, for example in the figures, although sensing elements or other components may deviate from ideal circuit behavior of electrical elements such as diodes, resistors, capacitors, etc.

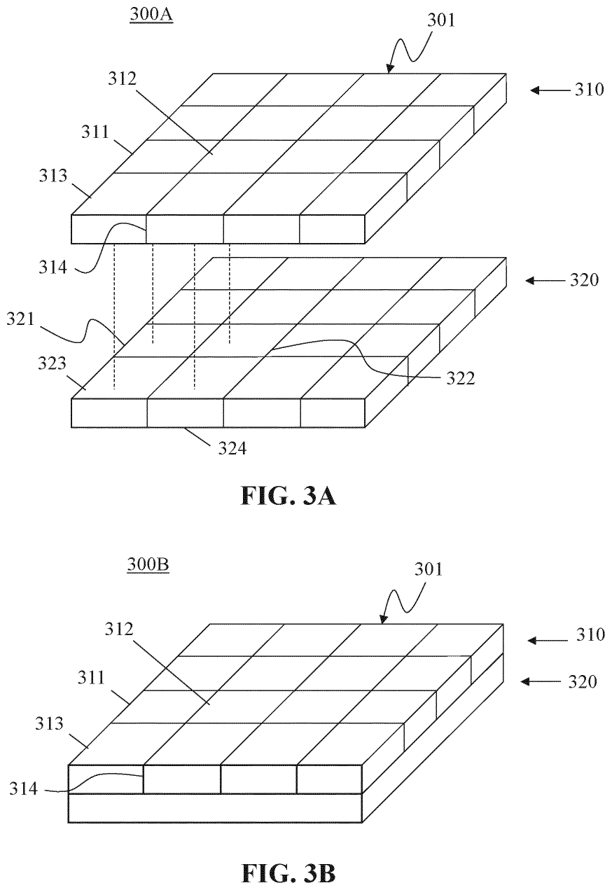

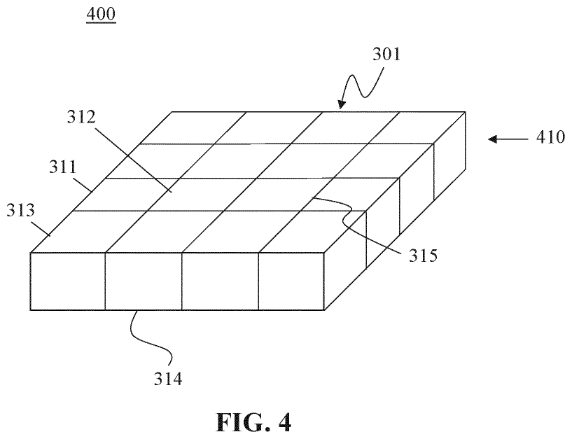

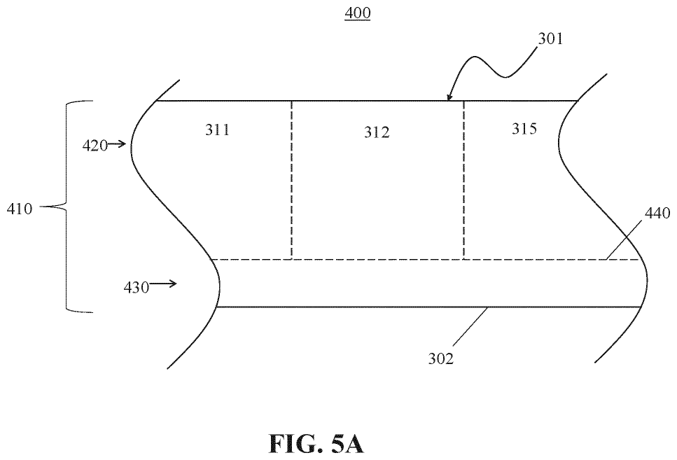

FIG. 3A and FIG. 3B illustrate exemplary structures of a detector, consistent with embodiments of the present disclosure. The detector may include an array of sensing elements. FIG. 4 shows another exemplary structure of a detector, consistent with embodiments of the present disclosure. A detector such as detector 300A, detector 300B, or detector 400 as shown in FIGS. 3A-3B and FIG. 4 may be provided as charged-particle detection device 244 as shown in FIG. 2A or detector 144 as shown in FIG. 2B. In FIG. 3A, detector 300A includes a sensor layer 310 and a signal processing layer 320. Sensor layer 310 may include a sensor die made up of multiple sensing elements, including sensing elements 311, 312, 313, and 314. In some embodiments, the multiple sensing elements may be provided in an array of sensing elements, the sensing elements having a uniform size, shape, and arrangement. A detection surface 301 may be included in a detector that is configured to receive charged particles.

Signal processing layer 320 may include a read-out integrated circuit (ROIC). Signal processing layer 320 may include multiple signal processing circuits, including circuits 321, 322, 323, and 324. The circuits may include interconnections or wiring paths configured to communicatively couple sensing elements. Each sensing element of sensor layer 310 may have a corresponding signal processing circuit in signal processing layer 320. Sensing elements and their corresponding circuits may be configured to operate independently. As shown in FIG. 3A, circuits 321, 322, 323, and 324 may be configured to communicatively couple to outputs of sensing elements 311, 312, 313, and 314, respectively, as shown by the four dashed lines between sensor layer 310 and signal processing layer 320.

Signal processing layer 320 may include circuit components configured to perform charged particle detection. For example, signal processing layer 320 may include an amplifier, logical components, switches, etc.

In some embodiments, signal processing layer 320 may be configured as a single die with multiple circuits provided thereon. Sensor layer 310 and signal processing layer 320 may be in direct contact. For example, as shown in FIG. 3B, which shows detector 300B, signal processing layer 320 can directly abut sensor layer 310.

In some embodiments, components and functionality of different layers may be combined or omitted. For example, signal processing layer 320 may be combined with sensor layer 310. Furthermore, a circuit for charged particle detection may be integrated at various points in a detector, for example in a separate read-out layer of a detector or on a separate chip. In some embodiments, a circuit for charged particle detection may be provided in the same chip as that having sensing elements provided thereon. Signal processing layer 320 may be made monolithic with sensor layer 310.

In some embodiments, a monolithic detector may be provided. The detector may include multiple regions that are integrated together. The detector may include sensing elements and circuitry configured to perform signal processing (e.g., a ROIC). The detector may include a monolithic layer.

As shown in FIG. 4, a detector 400 may be provided. Detector 400 may include a monolithic layer 410. Detector 400 may be configured to both receive charged particles and route output signals. Detector 400 may include a pixelated array of sensing elements and integrated readout circuitry.

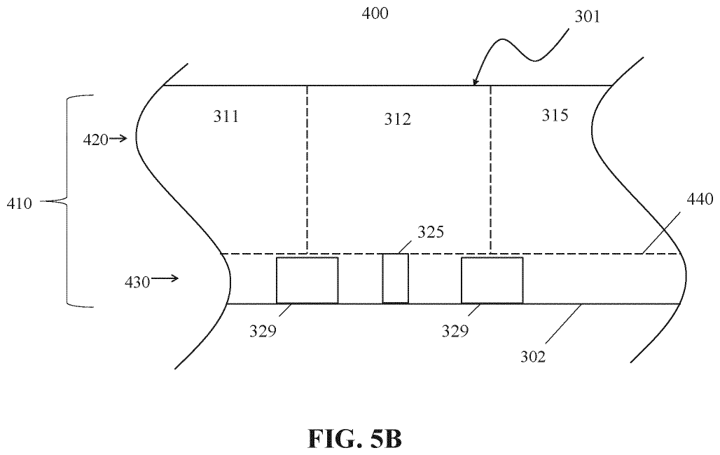

Detector 400 may be configured for back-side illumination. Detector 400 may include detection surface 301 that is configured to receive charged particles. As shown in FIG. 5A, monolithic layer 410 may include a first region 420 and a second region 430. Monolithic layer 410 may be the only layer provided in a detector chip. A first side of monolithic layer 410 may be configured to receive charged particles, and circuitry may be provided on a second side, opposite from the first side. The circuitry may include a circuit for charged particle detection, such as an electron counting circuit separately provided for each sensing element. The circuitry may be configured to output detection signals.

First region 420 of monolithic layer 410 may include a region sensitive to charged particles. First region 420 may include a volume configured to generate carriers in response to a charged particle being received at the sensing element. First region 420 may include a diode. The diode may be configured so that numerous carriers, such as pairs of electrons and holes, are generated in response to receiving a charged particle. The diode may include a PIN diode.

First region 420 may include sensing elements 311, 312, 313, 314, and 315. Each of sensing elements 311, 312, 313, 314, and 315 may represent a pixel that is a segment of a PIN diode with an internal mechanism of electron-hole pair generation. Although FIG. 4 shows sensing elements 311, 312, 313, 314, and 315 as separate bodies, such divisions may be merely schematic. Sensing elements 311, 312, 313, 314, and 315 may be contiguous with one another. In some embodiments, separation between sensing elements may be achieved by internal electric fields.

Each of sensing elements 311, 312, 313, 314, and 315 may be configured to generate a response to a charged particle event. For example, sensing element 311 may be configured to absorb energy deposited thereon by a particle (e.g., an incoming secondary electron) and generate carriers (e.g., electron-hole pairs) that are swept to the electrodes of sensing element 311 by an electric field. The carriers may be generated within the sensing element and may be fed to circuitry connected to the sensing element, including readout circuitry. In some embodiments, the circuitry may be integrated within a monolithic layer of a detector.

FIG. 5A is a diagrammatic representation of monolithic layer 410 of detector 400. FIG. 5A may represent a partial cross section of detector 400 showing an interior of monolithic layer 410. Monolithic layer 410 may be configured to have a plurality of regions stacked in a thickness direction, the thickness direction being substantially parallel to an incidence direction of a charged particle beam. For example, an electron beam may be incident on detector 400 at detection surface 301. The plurality of regions of monolithic layer 410 may include first region 420 and second region 430. First region 420 may be configured as a sensor layer. Second region 430 may be configured as a circuit layer or signal processing layer. Sensing elements, for example sensing elements 311, 312, and 315 may be provided in first region 420.

Although FIG. 5A depicts sensing elements 511, 512, and 513 as discrete units when viewed in cross-section, such divisions may not actually be present. For example, the sensing elements of a detector may be formed by a semiconductor device constituting a PIN diode device manufactured as a substrate with a plurality of regions including a p+ region, an intrinsic region, and an n+ region. Sensing elements 311, 312 and 315 may be contiguous in cross sectional view. Other components may also be provided that may be integral with the sensing elements.

As shown in FIG. 5A, second region 430 is provided adjacent to first region 420. Second region 430 may include a circuit that may be configured to function like signal processing layer 320 discussed above with reference to FIG. 3A or FIG. 3B. Second region 430 may comprise line wires, interconnects, switches, and various electronic circuit components. In some embodiments, second region 430 may comprise a processing system. Second region 430 may be configured to receive output charge or current detected in first region 420. Second region 430 may be configured to perform processing using an amplifier, comparator, and analog-to-digital converter, etc.

In some embodiments, insulation may be provided between first region 420 and second region 430. For example, an insulator 440 may be provided. Insulator 440 may be configured to insulate a volume sensitive to charged particles (e.g., an electron-sensitive volume of a diode) from circuitry that may be included in second region 430. Insulator 440 may be configured to isolate first region 420 from second region 430. It will be understood that a collection electrode (e.g., electrode 325 of FIG. 5B) is not insulated from first region 420. For example, charge or current may be configured to flow from a sensitive region included in sensing element 312 to electrode 325. From electrode 325, signals may be routed to circuitry or other components that may be isolated from first region 420, such as transistors 329.

In some embodiments, second region 430 may include switches. Switches may be provided between adjacent sensing elements in a horizontal direction in the cross-sectional view. In some embodiments, other components such as electrodes, wiring paths, and transistors configured to perform various functions may be provided in second region 430. Switches and other components may be formed outside the active area of the sensing elements (e.g., outside the electron-sensitive volume of diode).

Monolithic layer 410 may include a semiconductor substrate having a first side and a second side opposite from the first side. For example, as shown in FIG. 5A, monolithic layer 410 may have a first side that includes detection surface 301, and a second side 302 that is on an opposite side of monolithic layer 410. There may be multiple sensing elements formed in the first side of the substrate, each of the sensing elements configured to receive charged particles emitted from a sample. First region 420 may include multiple sensing elements formed on the first side of the substrate, such as sensing elements 311, 312, 315. Second region 430 may be formed on second side 302. Signal processing components, such as transistors, may be formed on second side 302.

Monolithic layer 410 may be formed from a single piece of planar material. The planar material may be a semiconductor substrate. Monolithic layer 410 may be formed from a wafer. In some embodiments, the wafer may be an epitaxial (“epi”) wafer. In some embodiments, the wafer may be a silicon-on-insulator (“SOI”) wafer. In some embodiments, the wafer may be a silicon carbide (“SiC”) wafer. The first side and the second side of monolithic layer 410 may comprise the top and bottom of the wafer. A thickness of the wafer may vary based on a nominal size of the wafer. For example, a broader wafer may have a larger thickness. In some embodiments, a thickness of monolithic layer 410 may be in a range from about 5 to 50 μm. In some embodiments, the thickness of monolithic layer 410 may be in a range from about 10 to 30 μm. In some embodiments, the thickness of the monolithic layer may be less than or equal to 30 μm. The thickness of monolithic layer 410 may be configured as any suitable dimension.

FIG. 5B is a diagrammatic representation of monolithic layer 410 of detector 400 having components provided in second region 430. Components provided in second region 430 may include electrodes, wiring paths, and transistors. As shown in FIG. 5B, second region 430 includes electrode 325 and transistors 329. Electrode 325 may be configured as a collection electrode. Carriers generated in first region 420 may be collected at electrode 325. Electrode 325 may be configured as a cathode. Detection surface 301 may be formed as an electrode (e.g., a thin conductive layer) and may be configured as an anode. A common anode may be formed on multiple sensing elements. Detection surface 301 may include the common anode. Individual cathodes may be provided for each sensing element.

Transistor 329 may be configured as a switch. Transistor 329 may be configured to connect adjacent sensing elements. Sensing elements may be connected in accordance with a grouping that may correspond with a single electron beam spot covering multiple sensing elements. Transistor 329 may be provided for other purposes. Furthermore, multiple transistors may be provided in second region 430. The view of FIG. 5B may be only a cross section at a particular point, and detector 400 may have different structures formed in second region 430 at different cross sections.

Second region 430 may include components that may be used for performing signal processing of outputs from sensing elements. For example, second region 430 may include circuitry configured to convert an output of a sensing element to an electrical signal of a different form. Second region 430 may include a transimpedance amplifier (TIA) that is configured to convert current collected from electrode 325 to a voltage.

Second region 430 may include a discriminator. The discriminator may be configured to make a determination based on a signal input thereto, and may output a different signal. The discriminator may be configured to compensate for signal effects using information based on known characteristics of electron arrival events, for example. The discriminator may be configured to receive an analog signal and output a digital signal. The discriminator may include a voltage comparator. When input voltage crosses a threshold, the discriminator may output a binary signal. For example, the discriminator may be configured to compare an input voltage signal to a fixed threshold (V_{TH}), and when the signal exceeds V_{TH}, the discriminator may output a binary “1” signal. In some embodiments, discriminator may use an adjustable threshold. There may be multiple thresholds that are used. The discriminator may be configured to indicate the detection of one electron. The discriminator may be configured to generate a counting signal that is used for counting electrons.

Further examples of components that may be included in second region 430 may be found in, for example, WO 2019/0378682 or U.S. application Ser. No. 17/044,840, which are herein incorporated by reference in their entireties.

A sensing element formed in a monolithic layer of a detector may be configured to generate a signal, such as an amplified charge or current, based on a received charged particle. The sensing element may be one of multiple sensing elements that may be formed on the first side of the detector. The sensing element may be configured to generate carriers in proportion to a first property of the received charged particle, such as an energy level. The carriers may form the signal that is output from the sensing element. An amplification mechanism such as impact ionization may cause numerous carriers to be generated. The amplified charge or current may be formed by the carriers being swept to an electrode of the detector. The electrode may be associated with the sensing element. For example, in FIG. 5B, carriers generated in sensing element 312 may be swept to electrode 325 and an amplified charge or current may be output from electrode 325. Each sensing element may have its own electrode that may be formed on the second side of the detector.

Signal processing components formed in a monolithic layer of a detector may be configured to process the amplified charge or current. The signal processing components may be formed on the second side of the monolithic layer. For example, in FIG. 5B, signal processing components may be formed in second region 430. The signal processing components may be part of a system configured to transform an output of a sensing element to an electrical signal of a different form. The system may be configured to determine a value that represents a second property of the received charged particle, such as a number of charged particles received by the one or more sensing elements. The value may be, for example, a voltage. The value may be determined based on the signal output from the sensing element. The system may be configured to convert the amplified charge or current of one or more sensing elements of the multiple sensing elements to a value that represents a second property of the received charged particle, such as a number of charged particles received by the one or more sensing elements. The one or more sensing elements may be grouped together. The second property of the received charged particle may include intensity of a secondary electron beam spot formed on the detector.

Components may be formed in second region 430 by various processes. In some embodiments, components may be formed in second region 430 by implantation. Components may be formed by CMOS processes. In some embodiments, components may be formed by depositing material to build up monolithic layer 410. Monolithic layer 410 may be formed as an epi-substrate, a SOI substrate, or a SiC substrate, for example.

In some embodiments, in addition to or instead of switches, components in second region 430 may include analog and digital signal processing components such as an amplifier, readout chain, digitalization device, and data output. A capacitive transimpedance amplifier (CTIA) may be one example of an amplifier. An analog-to-digital converter (ADC) may be one example of a digitalization device. In FIG. 5B, a CTIA may be configured to convert charge or current collected from electrode 325 to a voltage. An ADC may be configured to receive an input signal coming from electrode 325 and to output a signal representing a property of a charged particle received by the detector. The input signal coming from electrode 325 may be a signal transmitted from the CTIA.

In some embodiments, an epi-substrate may be used to form monolithic layer 410, and back side processing may be performed to incorporate components such as a CTIA, readout chain, ADC, and data output in second region 430.

In some embodiments, SOI or SiC may be used to form monolithic layer 410.

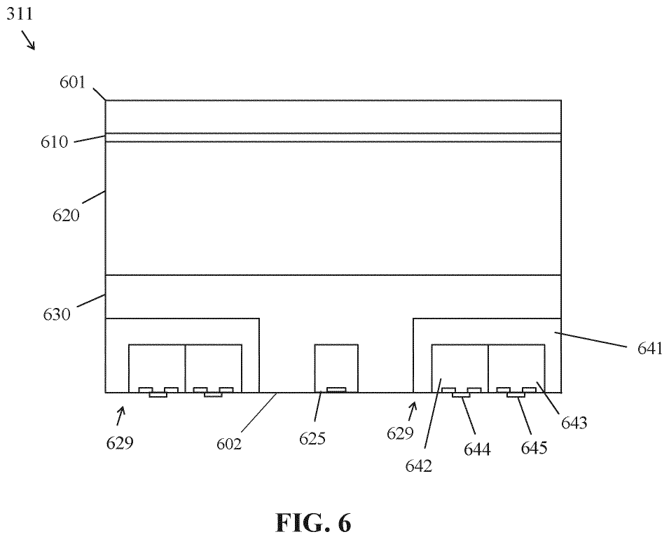

Reference is now made to FIG. 6, which is a diagrammatic representation of sensing element 311 that may form at least a part of monolithic layer 410. Sensing element 311 may be configured as a diode. Sensing element 311 may be formed using semiconductor processing, such as CMOS processes. Various regions of sensing element 311 may be formed by embedding regions into a substrate. Sensing element 311 may include semiconductor regions including a surface layer 601, a shallow p+ region 610, and a p epitaxial region 620. Surface layer 601 may be configured as a contact. Surface layer 601 may include or function similar to detection surface 301 (see FIGS. 3-5). Sensing element 311 may include a low dose n type implant region 630. Furthermore, electrode 625 and transistor 629 may also be provided that may be integrated with sensing element 311. Transistor 629 may include a deep p well 641, an n well 642, and a p well 643. A PMOS 644 and an NMOS 645 may be formed. Sensing element 311 may be configured so that a depletion region forms therein, with boundaries of the depletion region being region 610, electrode 625, and deep p well 641.

In FIG. 6, a first side of sensing element 311 may be formed by surface layer 601. A second side 602 may also be formed. Second side 602 may be opposite from the first side. Signal processing components may be formed on second side 602. A first region of a monolithic detector that includes sensing element 311 may include surface layer 601, region 610, p epitaxial region 620, and low dose n type implant region 630. A second region of the monolithic detector may include transistors 629 and electrode 625. An insulator may include deep p well 641.

In operation of a charged particle beam apparatus, a primary electron beam may be projected onto a sample, and secondary particles including secondary electrons or backscattered electrons may be directed from the sample to sensing element 311. Sensing element 311 may be configured so that an incoming electron generates carriers including electron-hole pairs in p epitaxial region 620. Numerous electron-hole pairs may be generated due to a mechanism triggered by the arrival of an incoming electron, such as impact ionization. Electrons or holes of the electron hole pairs may flow to electrode 625 and may form a current pulse in response to the incoming electron arriving at sensing element 311. Signal processing components formed on

Transistor 629 may be configured as a switching element. Transistor 629 may include a MOSFET. Transistor 629 may be used to connect sensing elements. Transistor 629 may demarcate the boundaries between sensing elements. For example, the region between transistors 629 may correspond to sensing element 311, while regions between other transistors may correspond to other sensing elements, including sensing element 312, 313, and 315. Each of sensing elements 311, 312, 313, 314, 315 may comprise outputs for making electrical connections to other components. Outputs may be integrated with transistor 629 or may be provided separately. Outputs may be integrated in region 630 at other cross-sectional locations not shown by FIG. 6.

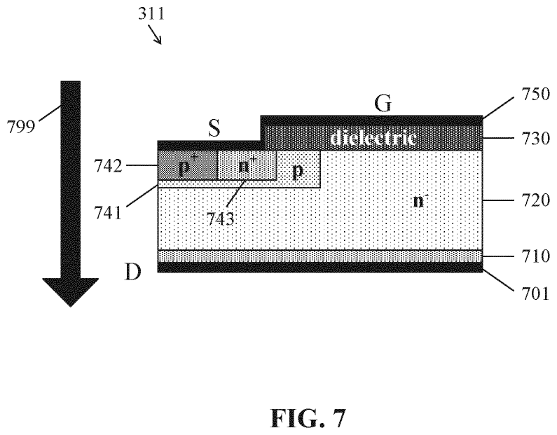

FIG. 7 is a diagrammatic representation of sensing element 311 that may form a portion of a monolithic layer, consistent with embodiments of the present disclosure. Sensing element 311 may include a surface region 701, a shallow region 710, an n− region 720, and a dielectric region 730. Contacts may be formed including contact S, contact D, and contact G. Sensing element 311 may include a well including p region 741, p+ region 742, and n+ region 743. Arrow 799 may indicate a flow of current that may be along a thickness direction of sensing element 311. Sensing element 311 as shown in FIG. 7 may be formed using SiC.

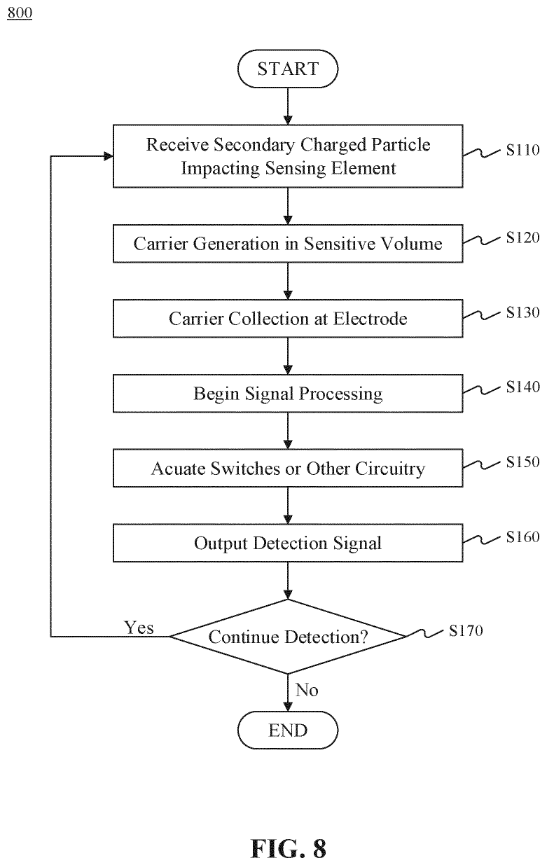

Reference is now made to FIG. 8, which is a flowchart illustrating a method 800 that may be useful for charged particle detection, consistent with embodiments of the disclosure. Method 800 may be performed by a controller of the charged-particle inspection system (e.g., controller 109 in FIG. 1 or FIG. 2B. In some embodiments, the controller may be included in second region 420 of monolithic layer 410. The controller may include circuitry (e.g., a memory and a processor) programmed to implement method 800. The controller may be an internal controller or an external controller coupled with the charged-particle inspection system.

As shown in FIG. 8, method 800 may begin at a “start” step. At the start step, a charged particle beam may be generated. The charged particle beam may be generated by electron beam tool 100. Generation of a primary charged particle beam may cause secondary beams to be formed that are directed to a detector of a charged particle beam apparatus. Detection may be started as charged particles begin impinging on the detector. The detector may include a sensing element (e.g., sensing element 311).

Method 800 may include a step S110 of receiving secondary charged particles impacting a sensing element.

Method 800 may include a step S120 of generating carriers in a sensitive volume of a sensing element. The carriers may be charge carriers (e.g., electrons or holes) that may be generated by an ionization process in response to a secondary charged particle impinging on the sensing element of the detector.

Method 800 may include a step S130 of performing carrier collection at an electrode. The electrode may be a cathode of a sensing element. Carriers generated in step S120 may be swept into the electrode and may be output as, for example, electrical current to another circuit component.

Method 800 may include a step S140 of performing signal processing. Step S140 may include performing signal processing of output of sensing elements included in the detector. Step S140 may include beginning sensing element output readout. Step S140 may include outputting current to another circuit component. Step S140 may include transmitting current through a wiring path that may be included in second region 430 of monolithic layer 410. Further signal processing may also be performed.

Method 800 may include a step S150 of actuating switches or other circuitry. The switches or other circuitry may be components included in second region 430 of monolithic layer 410. Switches may be actuated, for example, to connect grouped sensing elements. Switches may be actuated to manipulate signal readout paths. Actuation of other components may include, for example, amplifying an analog signal, comparing a signal to a reference value, or converting analog signals to digital signals.

Method 800 may include a step S160 of outputting a detection signal. Step S160 may include outputting a signal that represents an intensity of an electron beam spot on the detector. Step S160 may include transmitting a signal from a chip that forms the detector.

Method 800 may include a step S170 of determining whether to continue detection. Step S170 may include determining whether a scan of a region of interest on a sample has been completed. If it is determined in step S170 to continue detection, the method may return to step S110 and charged particles may continue to impact the sensing element. If it is determined in step S170 to not continue detection, the method may end.

A non-transitory computer-readable medium may be provided that stores instructions for a processor of a controller (e.g., controller 109 in FIG. 1) for detecting a charged particle beam according to the exemplary flowchart of FIG. 8, consistent with embodiments of the present disclosure. For example, the instructions stored in the non-transitory computer-readable medium may be executed by the circuitry of the controller for performing method 800 in part or in entirety. Common forms of non-transitory media include, for example, a floppy disk, a flexible disk, hard disk, solid-state drive, magnetic tape, or any other magnetic data storage medium, a Compact Disc Read-Only Memory (CD-ROM), any other optical data storage medium, any physical medium with patterns of holes, a Random Access Memory (RAM), a Programmable Read-Only Memory (PROM), and Erasable Programmable Read-Only Memory (EPROM), a FLASH-EPROM or any other flash memory, Non-Volatile Random Access Memory (NVRAM), a cache, a register, any other memory chip or cartridge, and networked versions of the same.

Block diagrams in the figures may illustrate the architecture, functionality, and operation of possible implementations of systems, methods, and computer hardware or software products according to various exemplary embodiments of the present disclosure. In this regard, each block in a schematic diagram may represent certain arithmetical or logical operation processing that may be implemented using hardware such as an electronic circuit. Blocks may also represent a module, segment, or portion of code that comprises one or more executable instructions for implementing the specified logical functions. It should be understood that in some alternative implementations, functions indicated in a block may occur out of the order noted in the figures. For example, two blocks shown in succession may be executed or implemented substantially concurrently, or two blocks may sometimes be executed in reverse order, depending upon the functionality involved. Some blocks may also be omitted. It should also be understood that each block of the block diagrams, and combination of the blocks, may be implemented by special purpose hardware-based systems that perform the specified functions or acts, or by combinations of special purpose hardware and computer instructions.

It will be appreciated that the embodiments of the present disclosure are not limited to the exact construction that has been described above and illustrated in the accompanying drawings, and that various modifications and changes can be made without departing from the scope thereof.

The embodiments may further be described using the following clauses:
1. A charged particle detector comprising:
a monolithic layer that includes:
   a first region including a plurality of sensing elements; and
   a second region including circuitry configured to process signals from the plurality of sensing elements.
2. The detector of clause 1, wherein the first region and the second region are stacked in a thickness direction of the detector.
3. The detector of clause 1 or clause 2, wherein the second region includes:
an electrode configured to collect carriers generated in the first region.
4. The detector of any one of clauses 1-3, further comprising:
a switch configured to connect adjacent sensing elements.
5. The detector of any one of clauses 1-4, wherein the second region includes:
circuitry configured to convert an output of a sensing element to an electrical signal of a different form.
6. The detector of any one of clauses 1-5, wherein the detector is formed as a pixelated array including the plurality of sensing elements.
7. The detector of any one of clauses 1-6, wherein the plurality of sensing elements includes a diode configured to generate electron-hole pairs in response to an incident electron impacting the detector.
8. The detector of clause 7, wherein the second region includes circuitry configured to generate an output signal in proportion to incoming current or charge signal generated in the diode.
9. A method of detecting charged particles, comprising:
receiving a charged particle impacting a sensing element;
generating carriers in a sensitive volume of the sensing element;
collecting the carriers at an electrode included in a monolithic layer of a detector that includes the sensing element; and
performing signal processing using a signal output from the electrode.
10. The method of clause 9, wherein the signal processing includes performing signal readout from the monolithic layer.
11. The method of clause 9 or clause 10, further comprising:
actuating a component included in the monolithic layer.
12. The method of clause 11, wherein the component includes a switch configured to connect adjacent sensing elements.
13. The method of clause 12, further comprising:
connecting adjacent sensing elements so that carriers from a plurality of sensing elements are output together.
14. The method of any one of clauses 9-14, further comprising:
outputting a detection signal that represents an intensity of an electron beam spot on the detector.
15. A non-transitory computer-readable medium storing a set of instructions that are executable by one or more processors of controller of a charged particle beam apparatus to cause the charged particle beam apparatus to perform a method comprising:
generating a charged particle beam;
receiving a secondary charged particle impacting a sensing element;
generating carriers in a sensitive volume of the sensing element;
collecting the carriers at an electrode included in a monolithic layer of a detector that includes the sensing element; and
performing signal processing using a signal output from the electrode.
16. The medium of clause 15, wherein the set of instructions are executable to cause the charged particle beam apparatus to:
perform signal readout from the monolithic layer.
17. The medium of clause 15 or clause 16, wherein the set of instructions are executable to cause the charged particle beam apparatus to:
actuate a component included in the monolithic layer.
18. The medium of clause 17, wherein the component includes a switch configured to connect adjacent sensing elements.
19. The medium of clause 18, wherein the set of instructions are executable to cause the charged particle beam apparatus to:
connect adjacent sensing elements so that carriers from a plurality of sensing elements are output together.
20. The medium of any one of clauses 15-19, wherein the set of instructions are executable to cause the charged particle beam apparatus to:
output a detection signal that represents an intensity of an electron beam spot on the detector.
21. A monolithic detector for a charged particle beam apparatus, the detector comprising:
a plurality of sensing elements formed on a first side of a semiconductor substrate, each of the sensing elements configured to receive charged particles emitted from a sample and to generate carriers in proportion to a first property of a received charged particle, the substrate having a thickness in a range from about 10 to 30 μm; and
a plurality of signal processing components formed on a second side of the semiconductor substrate, the second side being opposite the first side, the plurality of signal processing components being part of a system configured to determine a value that represents a second property of the received charged particle.
22. The detector of clause 21, wherein the detector is configured so that the carriers form a signal that is output from each of the sensing elements.
23. The detector of clause 22, wherein the signal includes an amplified charge or current.
24. The detector of clause 22 or clause 23, wherein the system is configured to convert the signal into the value that represents the second property of the received charged particle.
25. The detector of clause 24, wherein the value includes a voltage.
26. The detector of any one of clauses 21-25, wherein the plurality of signal processing components comprises:
a switch configured to connect adjacent sensing elements.
27. The detector of any one of clauses 21-26, wherein the plurality of signal processing components comprises:
circuitry configured to convert an output of a sensing element to an electrical signal of a different form.
28. The detector of any one of clauses 21-27, wherein the detector is formed as a pixelated array including the plurality of sensing elements.
29. The detector of any one of clauses 21-28, wherein the plurality of sensing elements includes a diode configured to generate electron-hole pairs in response to an incident electron impacting the detector.
30. The detector of clause 29, wherein the plurality of signal processing components includes circuitry configured to generate an output signal in proportion to incoming current or charge signal generated in the diode.
31. The detector of any one of clauses 21-30, wherein the plurality of signal processing components includes a transimpedance amplifier.
32. The detector of any one of clauses 21-31, wherein the charged particle beam apparatus includes a scanning electron microscope.
33. The detector of any one of clauses 21-32, wherein the semiconductor substrate includes an epitaxial substrate.
34. The detector of any one of clauses 21-32, wherein the semiconductor substrate includes a silicon-on-insulator substrate.
35. The detector of any one of clauses 21-32, wherein the semiconductor substrate includes a silicon carbide substrate.
36. The detector of any one of clauses 21-35, further comprising an electrode configured to collect the carriers for each of the sensing elements.
37. A monolithic detector for a charged particle beam apparatus, the detector comprising:
a plurality of sensing elements formed on a first side of a semiconductor substrate, each of the sensing elements configured to receive charged particles emitted from a sample and to generate carriers in proportion to a first property of a received charged particle; and
a plurality of signal processing components formed on a second side of the semiconductor substrate, the second side being opposite the first side, the plurality of signal processing components being part of a system configured to determine a value that represents a second property of the received charged particle,
wherein the substrate includes a region configured to insulate the plurality of sensing elements formed on the first side from the plurality of signal processing components formed on the second side.
38. The detector of clause 37, wherein the detector is configured so that the carriers form a signal that is output from each of the sensing elements.
39. The detector of clause 38, wherein the signal includes an amplified charge or current.
40. The detector of clause 38 or clause 39, wherein the system is configured to convert the signal into the value that represents the second property of the received charged particle.
41. The detector of clause 40, wherein the value includes a voltage.
42. The detector of any one of clauses 37-41, wherein the plurality of signal processing components comprises:
a switch configured to connect adjacent sensing elements.
43. The detector of any one of clauses 37-42, wherein the plurality of signal processing components comprises:
circuitry configured to convert an output of a sensing element to an electrical signal of a different form.
44. The detector of any one of clauses 37-43, wherein the detector is formed as a pixelated array including the plurality of sensing elements.
45. The detector of any one of clauses 37-44, wherein the plurality of sensing elements includes a diode configured to generate electron-hole pairs in response to an incident electron impacting the detector.
46. The detector of clause 45, wherein the plurality of signal processing components includes circuitry configured to generate an output signal in proportion to incoming current or charge signal generated in the diode.
47. The detector of any one of clauses 37-46, wherein the plurality of signal processing components includes a transimpedance amplifier.
48. The detector of any one of clauses 37-47, wherein the charged particle beam apparatus includes a scanning electron microscope.
49. The detector of any one of clauses 37-48, wherein the semiconductor substrate includes an epitaxial substrate.
50. The detector of any one of clauses 37-48, wherein the semiconductor substrate includes a silicon-on-insulator substrate.
51. The detector of any one of clauses 37-48, wherein the semiconductor substrate includes a silicon carbide substrate.
52. A method of detecting charged particles, comprising:
   receiving a charged particle impacting a sensing element;
   generating carriers in a sensitive volume of the sensing element;
   collecting the carriers at an electrode included in a monolithic layer of a detector that includes the sensing element; and
   performing signal processing using a signal output from the electrode.
53. The method of clause 52, wherein the signal processing includes performing signal readout from the monolithic layer.
54. The method of clause 52 or clause 53, further comprising:
actuating a component included in the monolithic layer.
55. The method of clause 54, wherein the component includes a switch configured to connect adjacent sensing elements.
56. The method of clause 55, further comprising:
connecting adjacent sensing elements so that carriers from a plurality of sensing elements are output together.
57. The method of any one of clauses 52-56, further comprising:
outputting a detection signal that represents an intensity of an electron beam spot on the detector.
58. A non-transitory computer-readable medium storing a set of instructions that are executable by one or more processors of controller of a charged particle beam apparatus to cause the charged particle beam apparatus to perform a method comprising:
   generating a charged particle beam;
   receiving a secondary charged particle impacting a sensing element;
   generating carriers in a sensitive volume of the sensing element;
   collecting the carriers at an electrode included in a monolithic layer of a detector that includes the sensing element; and
   performing signal processing using a signal output from the electrode.
59. The medium of clause 58, wherein the set of instructions are executable to cause the charged particle beam apparatus to:
perform signal readout from the monolithic layer.
60. The medium of clause 58 or clause 59, wherein the set of instructions are executable to cause the charged particle beam apparatus to:
actuate a component included in the monolithic layer.
61. The medium of clause 60, wherein the component includes a switch configured to connect adjacent sensing elements.
62. The medium of clause 61, wherein the set of instructions are executable to cause the charged particle beam apparatus to:
connect adjacent sensing elements so that carriers from a plurality of sensing elements are output together.
63. The medium of any one of clauses 58-62, wherein the set of instructions are executable to cause the charged particle beam apparatus to:
output a detection signal that represents an intensity of an electron beam spot on the detector.

1. A monolithic detector for a charged particle beam apparatus, the detector comprising:
a plurality of sensing elements formed on a first side of a semiconductor substrate, each of the sensing elements configured to receive charged particles emitted from a sample and to generate carriers in proportion to a first property of a received charged particle, the substrate having a thickness in a range from about 10 to 30 μm; and
a plurality of signal processing components formed on a second side of the semiconductor substrate, the second side being opposite the first side, the plurality of signal processing components being part of a system configured to determine a value that represents a second property of the received charged particle.

2. The detector of claim 1, wherein the detector is configured so that the carriers form a signal that is output from each of the sensing elements.

3. The detector of claim 2, wherein the signal includes an amplified charge or current.

4. The detector of claim 2, wherein the system is configured to convert the signal into the value that represents the second property of the received charged particle.

5. The detector of claim 4, wherein the value includes a voltage.

6. The detector of claim 1, wherein the plurality of signal processing components comprises:
a switch configured to connect adjacent sensing elements.

7. The detector of claim 1, wherein the plurality of signal processing components comprises:
circuitry configured to convert an output of a sensing element to an electrical signal of a different form.

8. The detector of claim 1, wherein the detector is formed as a pixelated array including the plurality of sensing elements.

9. The detector of claim 1, wherein the plurality of sensing elements includes a diode configured to generate electron-hole pairs in response to an incident electron impacting the detector.

10. The detector of claim 9, wherein the plurality of signal processing components includes circuitry configured to generate an output signal in proportion to incoming current or charge signal generated in the diode.

11. The detector of claim 1, wherein the plurality of signal processing components includes a transimpedance amplifier.

12. The detector of claim 1, wherein the charged particle beam apparatus includes a scanning electron microscope.

13. The detector of claim 1, wherein the semiconductor substrate includes an epitaxial substrate.

14. The detector of claim 1, wherein the semiconductor substrate includes a silicon-on-insulator substrate.

15. The detector of claim 1, wherein the semiconductor substrate includes a silicon carbide substrate.

16. A non-transitory computer-readable medium storing a set of instructions that are executable by one or more processors of controller of a charged particle beam apparatus to cause the charged particle beam apparatus to perform operations comprising:
generating a charged particle beam;
receiving a secondary charged particle impacting a sensing element;
generating carriers in a sensitive volume of the sensing element;
collecting the carriers at an electrode included in a monolithic layer of a detector that includes the sensing element; and
performing signal processing using a signal output from the electrode.

17. The medium of claim 16, wherein the operations further comprise:
performing signal readout from the monolithic layer.

18. The medium of claim 16, wherein the operations further comprise:
actuating a component included in the monolithic layer.

19. The medium of claim 18, wherein the component includes a switch configured to connect adjacent sensing elements.

20. The medium of claim 19, wherein the operations further comprise:
connecting adjacent sensing elements so that carriers from a plurality of sensing elements are output together.
